(19) United States
(12) Patent Application Publication
(10) Pub. No.: US 2015/0129912 A1
(43) Pub. Date: May 14, 2015

(54) LIGHT-EMITTING DEVICE PACKAGE

(71) Applicant: Industrial Technology Research Institute, Hsinchu (TW)

(72) Inventors: Mei-Tan Wang, Miaoli County (TW); Jung-Min Hwang, Hsinchu City (TW); Chun-Ting Lin, Taipei City (TW); Chiun-Lern Fu, Hsinchu County (TW)

(73) Assignee: Industrial Technology Research Institute, Hsinchu (TW)

(21) Appl. No.: 14/138,149

(22) Filed: Dec. 23, 2013

(30) Foreign Application Priority Data
Nov. 14, 2013 (TW) 102141480

(51) Int. Cl. H01L 33/58

(52) U.S. Cl. CPC H01L 33/58
USPC 257/98

(57) ABSTRACT

A light-emitting device package including a substrate, a packaging lens, a light-emitting unit and a plurality of optical microstructures is provided. The packaging lens and the light-emitting unit are disposed on the substrate and the packaging lens wraps the light-emitting unit. The packaging lens has a bottom surface and includes at least one platform. The at least one platform has a side surface and a platform surface. The bottom surface of the packaging lens is connected with the platform surface through the side surface. The platform surface faces away from the light-emitting unit and the bottom surface. The optical microstructures are located on the platform surface of the at least one platform.

### CROSS-REFERENCE TO RELATED APPLICATION

This application claims the priority benefit of Taiwan application serial no. 102141480, filed on Nov. 14, 2013. The entirety of the above-mentioned patent application is hereby incorporated by reference herein and made a part of this specification.

### BACKGROUND

1. Technical Field

The disclosure relates to a package. Particularly, the disclosure relates to a light-emitting device package.

2. Related Art

In recent years, light-emitting efficiency and service life of light-emitting diode (LED) are enhanced, and since the LED has device features and advantages of low power consumption, low pollution, high efficiency, high response speed, small volume, light weight and capable of being disposed on various surfaces, the LEDs are widely used in various optical fields. Taking the application of the LED in illumination as an example, applications of applying LED packages in light sources (for example, lamps, street light, flashlights, etc.) or related illumination equipment have been developed.

Generally, a manufacturing process of the LED package requires optical designing twice to meet a product application requirement. In detail, during a packaging process of the LED, a first optical design is required to optimize a light-emitting angle, amount of light flux, a light intensity distribution and a color temperature distribution range of the LEDs. Then, a second optical design is implemented by disposing an optical lens, a diffusion plate or other optical devices on a light transmission path of the LED package, so as to change the optical performance of the LED package (for example, change the light-emitting angle and increase color uniformity). In other words, a purpose of the first optical design is to increase a light-emitting efficiency of the LED package as far as possible, and a purpose of the second optical design is to ensure that the light emitted from the whole light system satisfies a design requirement.

### SUMMARY

The disclosure provides a light-emitting device package including a substrate, a packaging lens, a light-emitting unit and a plurality of optical microstructures. The light-emitting unit is disposed on the substrate. The packaging lens is disposed on the substrate and wraps the light-emitting unit. The packaging lens has a bottom surface and includes at least one platform. The at least one platform has a side surface and a platform surface. The bottom surface of the packaging lens is connected with the platform surface of the at least one platform through the side surface of the at least one platform. The platform surface faces away from the light-emitting unit and the bottom surface. The optical microstructures are located on the platform surface of the at least one platform.

In order to make the aforementioned and other features of the disclosure comprehensible, several exemplary embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A is a structural schematic diagram of a light-emitting device package according to an embodiment of the disclosure.

FIG. 1B is a schematic diagram of a packaging lens of FIG. 1A.

FIG. 1C is a cross-sectional view of the packaging lens of FIG. 1A.

FIG. 1D is a light shape distribution diagram of the light-emitting device package of FIG. 1A.

FIG. 1E is an optical simulation data diagram of luminous intensity of the light-emitting device package of FIG. 1A.

FIG. 1F is a structural schematic diagram of a light-emitting device package according to a comparison embodiment of the disclosure.

FIG. 1G is an optical simulation data diagram of luminous intensity of the light-emitting device package of FIG. 1F.

FIG. 2A is a structural schematic diagram of a light-emitting device package according to another embodiment of the disclosure.

FIG. 2B is a structural schematic diagram of a light-emitting device package according to still another embodiment of the disclosure.

FIG. 2C is a structural schematic diagram of a light-emitting device package according to yet another embodiment of the disclosure.

FIG. 3A is a schematic diagram of another packaging lens according to an embodiment of the disclosure.

FIG. 3B is a cross-sectional view of the packaging lens of FIG. 3A.

FIG. 3C is a light shape distribution diagram when the packaging lens of FIG. 3A is applied to a light-emitting device package.

FIG. 3D is an optical simulation data diagram of luminous intensity when the packaging lens of FIG. 3A is applied to a light-emitting device package.

FIG. 4A is a schematic diagram of still another packaging lens according to an embodiment of the disclosure.

FIG. 4B is a cross-sectional view of the packaging lens of FIG. 4A.

### DETAILED DESCRIPTION OF DISCLOSED EMBODIMENTS

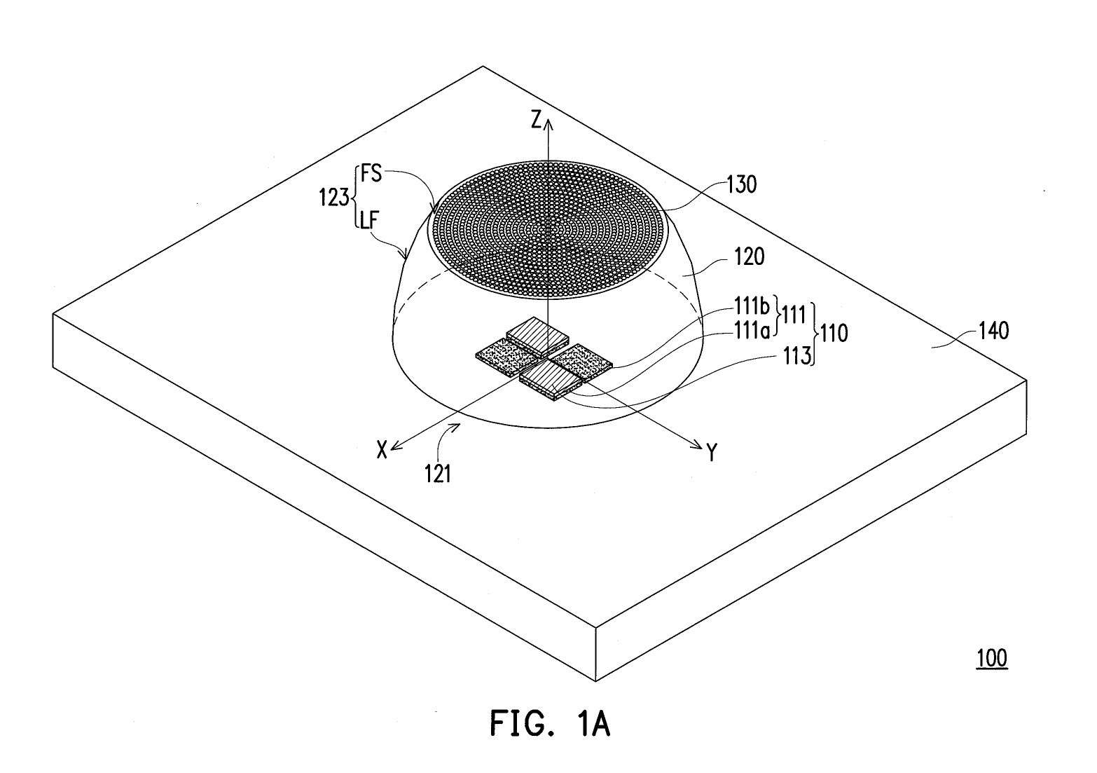

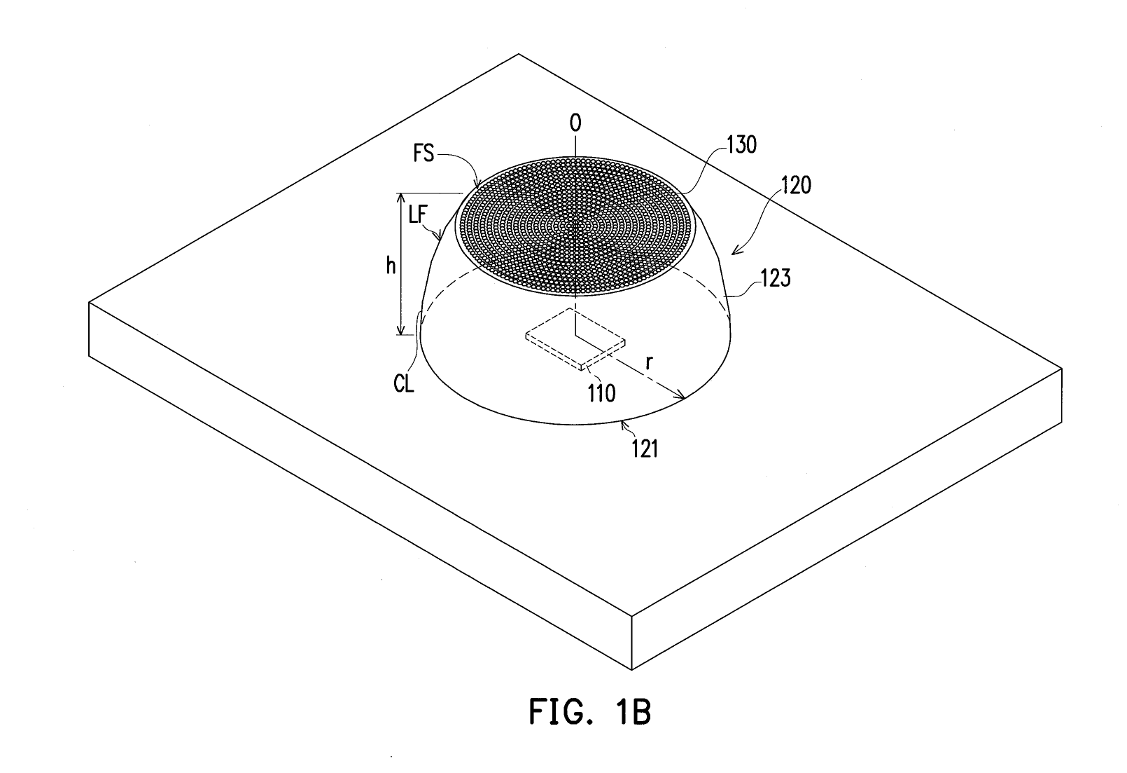

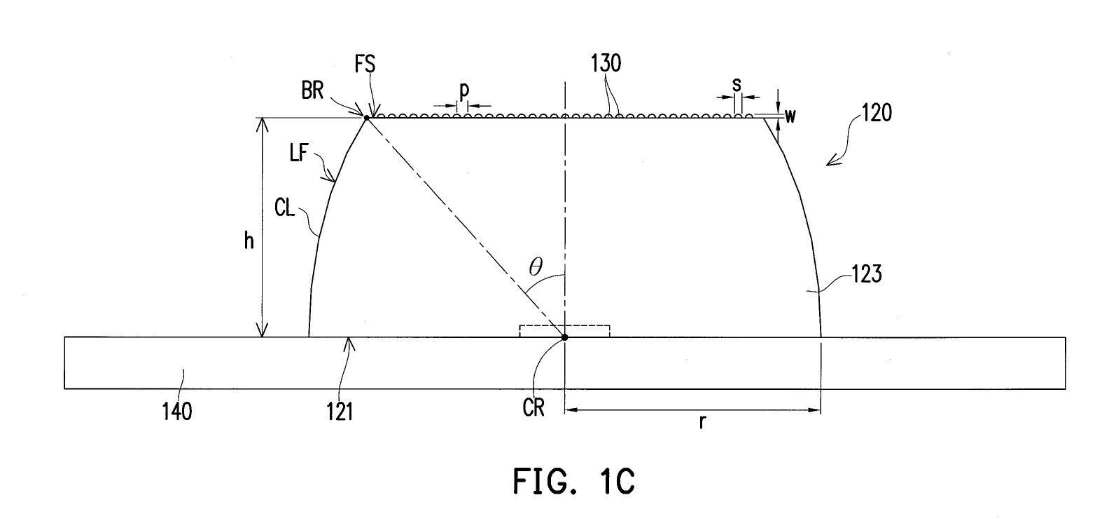

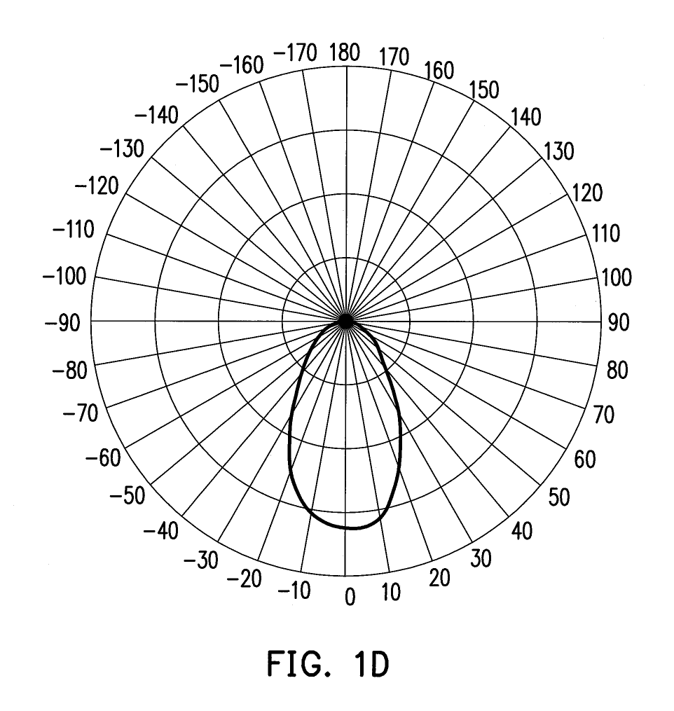

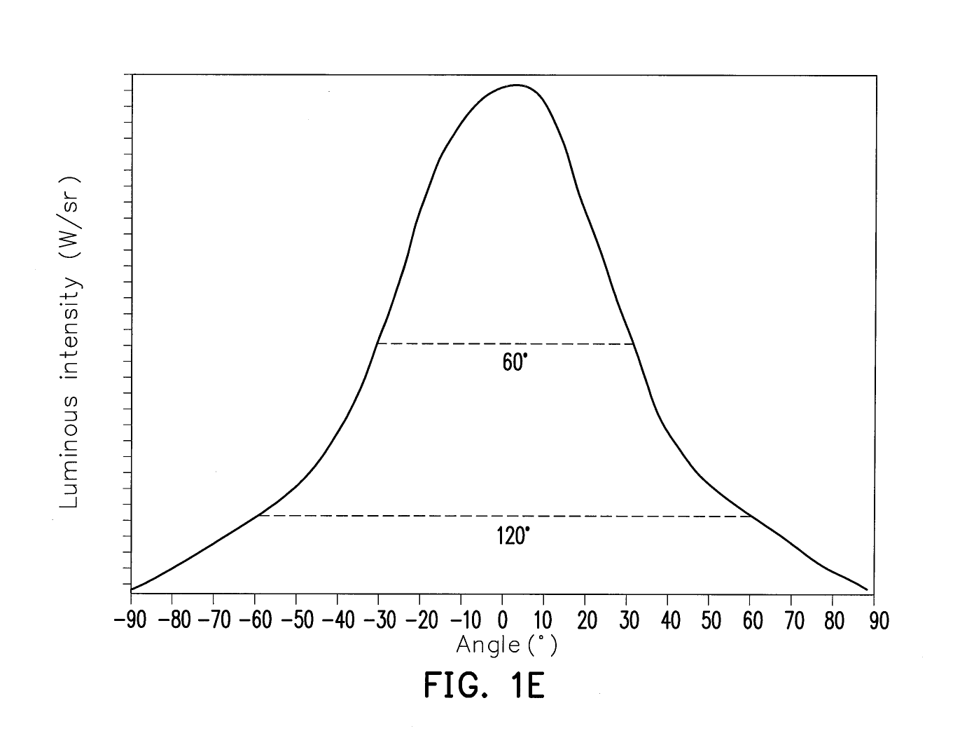

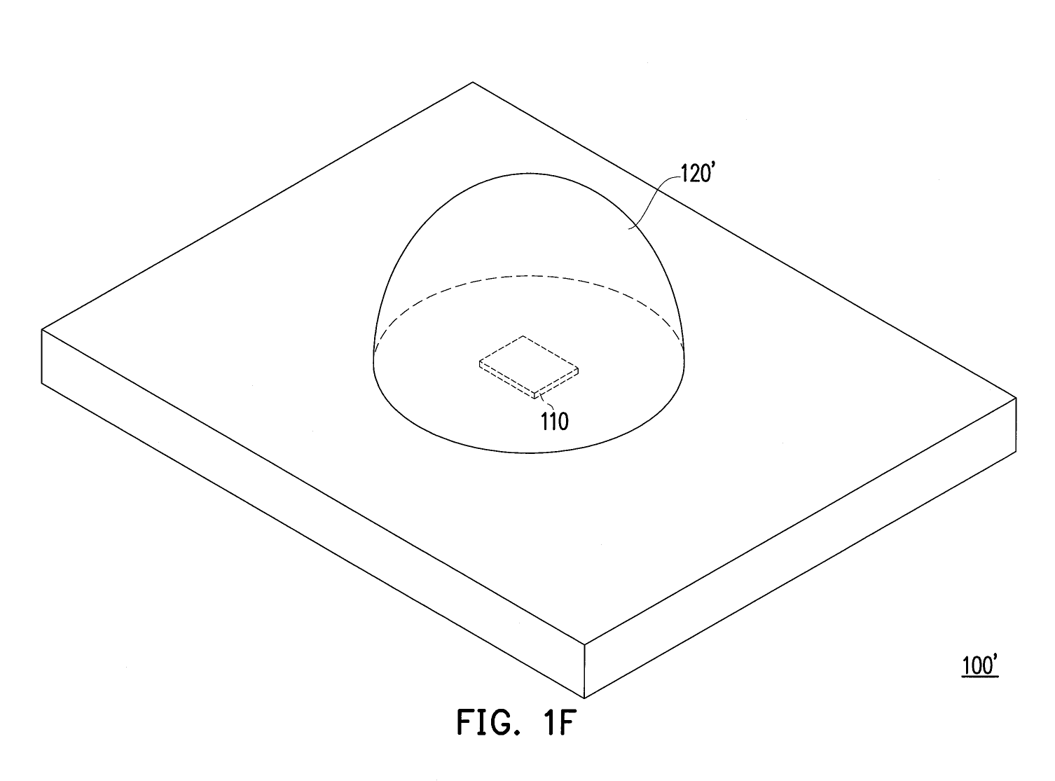

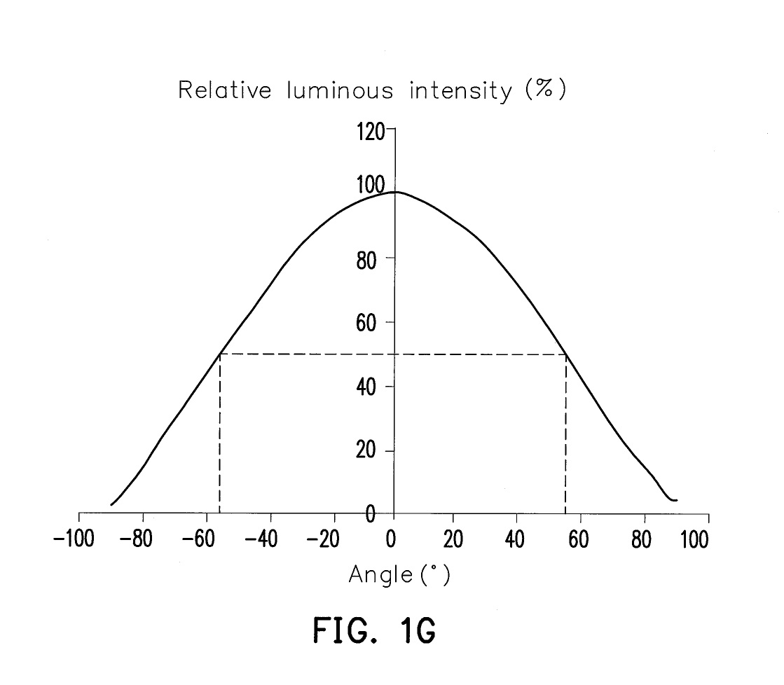

FIG. 1A is a structural schematic diagram of a light-emitting device package according to an embodiment of the disclosure. Referring to FIG. 1A, the light-emitting device package 100 includes a light-emitting unit 110, a packaging lens 120, and a plurality of optical microstructures 130. On the other hand, as shown in FIG. 1A, the light-emitting device package 100 further includes a substrate 140. The packaging lens 120 and the light-emitting unit 110 are disposed on the substrate 140. The packaging lens 120 wraps the light-emitting unit 110, and the optical microstructures 130 are disposed on the packaging lens 120. For example, in the present embodiment, the substrate 140 is a high thermal conductive substrate. Moreover, in the present embodiment, a material of the packaging lens 120 is silicon gel or a packaging material having characteristics of high light transmittance, low light absorption rate, high heat resistance and uneasy to be yellowed or deteriorated. On the other hand, in the present embodiment, the light-emitting unit 110 includes at least one light-emitting diode (LED) chip, and is capable of emitting a light beam.

In detail, in the present embodiment, the light-emitting unit 110 includes a plurality of light-emitting devices 111 arranged on the substrate 140. In the present embodiment, colors or color temperatures of at least part of the light-emitting devices 111 are different. For example, as shown in FIG. 1A, in the present embodiment, the light-emitting unit 110 includes a plurality of blue LED chips 111a and a plurality of red LED chips 111b, and the blue LED chips 111a and the red LED chips 111b are symmetrically arranged in alternation in the packaging lens 120, so as to meet the requirement of light-emitting symmetry. Moreover, the light-emitting unit 110 further includes a wavelength conversion material 113, and the wavelength conversion material 113 is disposed on the blue LED chips 111a to convert a blue light into a white light. In the present embodiment, the wavelength conversion material 113 can be a yellow phosphor layer. Moreover, configuration of the red LED chips 111b may enhance color rendering index of the light-emitting unit 110.

Further, in the present embodiment, since the packaging lens 120 wraps the light-emitting unit 110, and the optical microstructures 130 are disposed on the packaging lens 120, a light shape and color uniformity of the light-emitting unit 110 can be adjusted by changing a structure of the packaging lens 120 and a configuration distribution of the optical microstructures 130, which is further described below with reference of FIG. 1B.

FIG. 1B is a schematic diagram of the packaging lens of FIG. 1A. FIG. 1C is a cross-sectional view of the packaging lens of FIG. 1A. Referring to FIG. 1B, in the present embodiment, the packaging lens 120 has a bottom surface 121 and includes at least one platform 123. In the present embodiment, the platform 123 has a side surface LF and a platform surface FS. The bottom surface 121 of the packaging lens 120 is connected with the platform surface FS of the platform 123 through the side surface LF of the platform 123. The side surface LF is an ellipsoidal surface, a non-spherical or spherical surface, but the disclosure is not limited thereto. In detail, the bottom surface 121 of the packaging lens 120 has a radius r, and a vertical distance between the platform surface FS of the platform 123 and the bottom surface 121 is a height h. Moreover, as shown in FIG. 1A, the platform surface FS of the platform 123 faces away from the light-emitting unit 110 and the bottom surface 121, and the platform surface FS is substantially parallel to the substrate 140, and is substantially parallel to a light-emitting surface of the light-emitting unit 110.

Further, in the present embodiment, the packaging lens 120 further includes an optical axis O. The platform 123 of the packaging lens 120 is axial symmetric relative to the optical axis O, and the light-emitting unit 110 is disposed adjacent to the optical axis O. In the present embodiment, the light-emitting unit 110 is symmetrically disposed on the optical axis O. In detail, as shown in FIG. 1C, in the present embodiment, a section line CL of the side surface LF of the platform 123 cut through the optical axis O is a curved line, and the section line CL has a curvature R. Further, in the present embodiment, by adjusting a radius r of the packaging lens 120, the height h and the curvature R, the light beam emitted by the light-emitting unit 110 may have a proper light shape when the light beam emits out of the packaging lens 120. Generally, in case that the radius r of the packaging lens 120 is fixed, when the height h or the curvature R is increased, the light shape of the light beam emitting out of the packaging lens 120 is more convergent, i.e. a light-emitting angle is decreased. Moreover, in case of the same height h, the greater the curvature R is, the more convergent the light shape is. For example, in the present embodiment, the height h of the packaging lens 120 is smaller than or equal to 5 mm, and an included angle θ between the optical axis O and a connecting line with an edge BR of the platform surface FS of the at least one platform 123 and a geometric center CR of the bottom surface 121 falls within a range between 5 degrees and 60 degrees. It should be noticed that the above value range is only used as an example, and the disclosure is not limited thereto.

On the other hand, as shown in FIG. 1B, in the present embodiment, the optical microstructures 130 are disposed on the platform surface FS of the platform 123. For example, in the present embodiment, the optical microstructures 130 can be formed through high precision microstructure mold injection, and since the optical microstructures 130 are located on the platform surface FS of the platform 123, de-moulding of the optical microstructures 130 is easy, and it is not liable to cause damage of the optical microstructures 130 during de-moulding. Moreover, in the present embodiment, the optical microstructures 130 are hemispherical blocks, but the disclosure is not limited thereto. In other embodiments, the optical microstructures 130 can also be spherical blocks, cylindrical blocks, tapered blocks or any other regular or irregular blocks.

Further, when the light beam of the light-emitting unit 110 passes through the optical microstructures 130, the light beam is scattered. In other words, by configuring the optical microstructures 130, the light beam emitted by the light-emitting unit 110 may have a uniform scattering effect, such that luminance of the light beam is uniform when it is emitted. Further, in the present embodiment, by adjusting a size s, a pitch p and a height w of the optical microstructures 130, color uniformity of the light beam emitted by the light-emitting unit 110 can be ameliorated, and the light-emitting angle of the light beam can be controlled. For example, as shown in FIG. 1C, in the present embodiment, the pitch p between the microstructures 130 is smaller than or equal to 500 μm, and the height w is smaller than or equal to 500 μm. It should be noticed that the above value ranges are only used as an example, and the disclosure is not limited thereto.

In this way, a hot spot phenomenon generated at a center and an edge of the light-emitting device package 100 due to uneven illumination is avoided, and meanwhile a high light-emitting efficiency of the light-emitting device package 100 is maintained, so as to meet the requirements of low cost, small volume and high illumination quality. The functions of the light-emitting device package are further described below with reference of FIG. 1D-FIG. 1G.

FIG. 1D is a light shape distribution diagram of the light-emitting device package of FIG. 1A. FIG. 1E is an optical simulation data diagram of luminous intensity of the light-emitting device package of FIG. 1A. In FIG. 1D, a 0° direction corresponds to an upward direction along the optical axis O of FIG. 1B, a +90° direction corresponds to a rightward direction perpendicular to the optical axis O of FIG. 1B, a −90° direction corresponds to a leftward direction perpendicular to the optical axis O of FIG. 1B, a radial direction corresponds to a luminous intensity, and the greater the farther away from the center, the greater the luminous intensity is. In the luminous intensity diagram of FIG. 1E, a vertical axis represents the luminous intensities with a unit of watt per steradian (W/sr), and a horizontal axis represents angles included with the optical axis O. As shown in FIG. 1D to FIG. 1E, in the present embodiment, the light-emitting device package 100 can still provide a small angle light-emitting effect in case that the height h of the packaging lens 120 is smaller than or equal to 5 mm. In detail, in the present embodiment, a divergence angle of the light-emitting device package 100 may fall within a range between 100 degrees and 240 degrees. For example, when the divergence angle of the light-emitting device package 100 is 100 degrees, the light shape of the light-emitting device package 100 is mainly distributed from −50 degrees to 50 degrees, and when the divergence angle of the light-emitting device package 100 is 240 degrees, the light shape of the light-emitting device package 100 is mainly distributed from −120 degrees to 120 degrees, but the disclosure is not limited thereto. As shown in FIG. 1D, in the present embodiment, the light shape of the light-emitting device package 100 is mainly distributed from about −90 degrees to about 90 degrees. Moreover, in the present embodiment, a full width at half maximum (FWHM) of the luminous intensity curve of the light-emitting device package 100 falls within a range between 25 degrees and 60 degrees. For example, when the FWHM of the luminous intensity curve of the light-emitting device package 100 is 25 degrees, the FWHM of the luminous intensity curve of the light-emitting device package 100 can be extended to 12.5 degrees from −12.5 degrees, and when the FWHM of the luminous intensity curve of the light-emitting device package 100 is 60 degrees, the FWHM of the luminous intensity curve of the light-emitting device package 100 can be extended to 30 degrees from −30 degrees (as shown in FIG. 1E), but the disclosure is not limited thereto. It should be noticed that the above value ranges are only used as an example, and the disclosure is not limited thereto.

FIG. 1F is a structural schematic diagram of a light-emitting device package according to a comparison embodiment of the disclosure. FIG. 1G is an optical simulation data diagram of luminous intensity of the light-emitting device package of FIG. 1F. The drawing method of FIG. 1G is similar to FIG. 1E, and description thereof is not repeated. Referring to FIG. 1F, the light-emitting device package 100′ of the present embodiment is similar to the light-emitting device package 100 of FIG. 1A, and a difference there between is that the top of the packaging lens 120′ of the light-emitting device package 100′ is a smooth curve. For example, in the present embodiment, the packaging lens 120′ is a spherical surface. In other words, the light-emitting device package 100′ does not have the platform 123 and the optical microstructures 130 of the light-emitting device package 100. As shown in FIG. 1G, the FWHM of the luminous intensity curve of the light-emitting device package 100′ is about 120 degrees, which is distributed between −60 degrees and 60 degrees. In other words, compared to the light-emitting device package 100′, the light-emitting device package 100 may achieve the small angle light-emitting effect.

According to the above descriptions, by configuring the at least one platform 123 and the optical microstructures 130, the light-emitting device package 100 may achieve effects of high color uniformity and height-controlled light shape in case of one package (i.e. the packaging lens 120 is one lens), so as to effectively decrease package cost and a whole volume of the package.

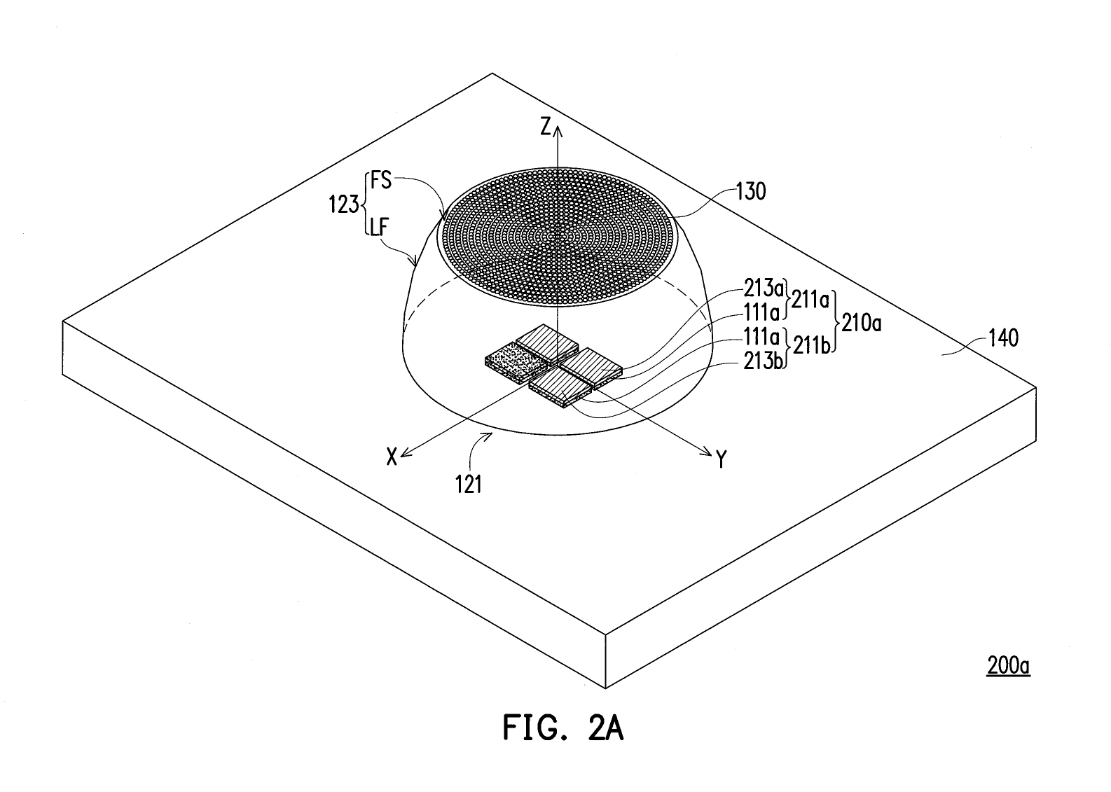

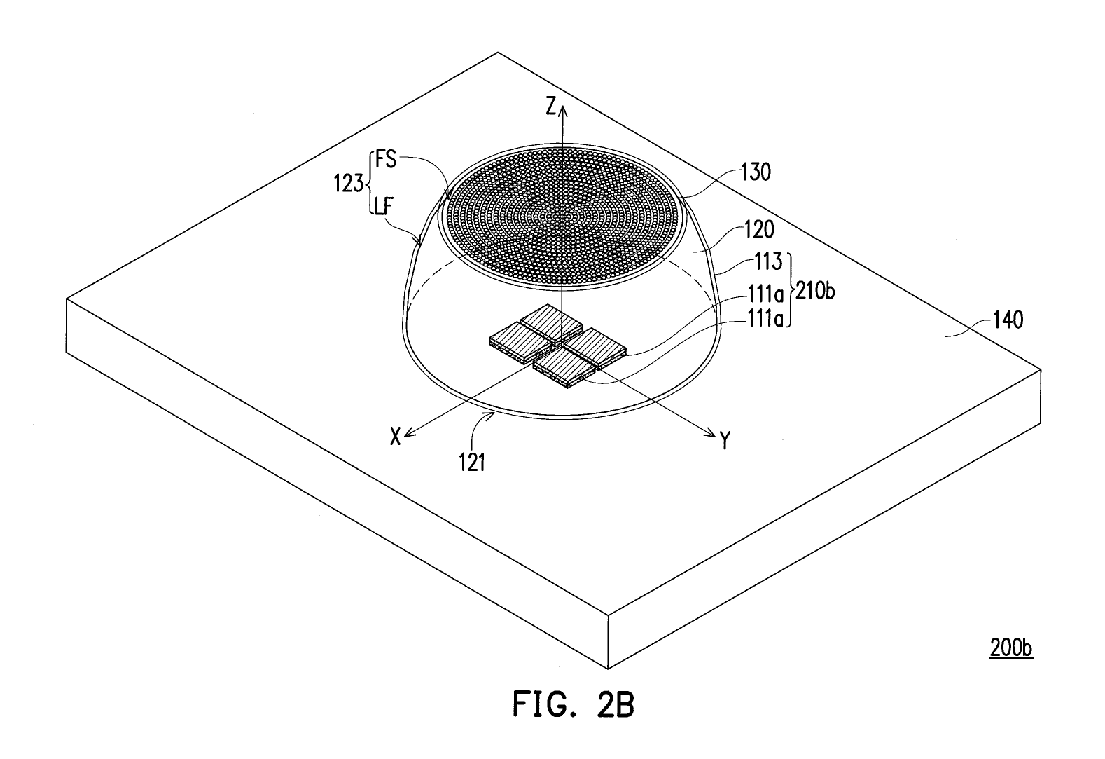

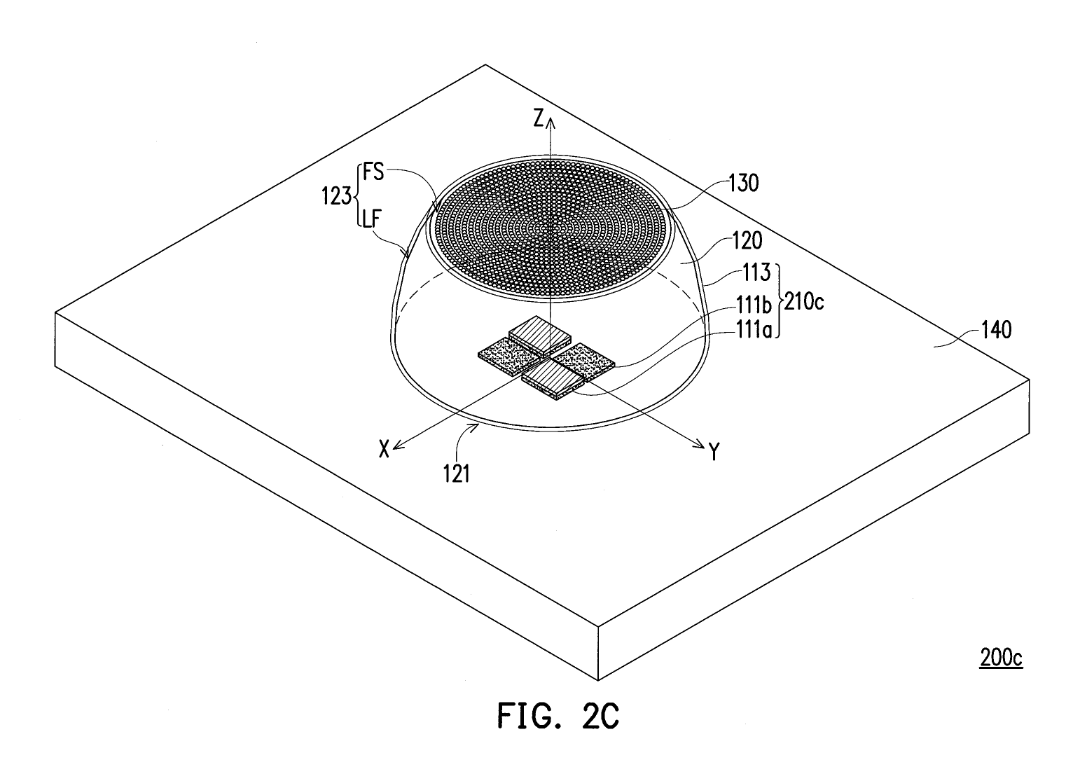

FIG. 2A is a structural schematic diagram of a light-emitting device package according to another embodiment of the disclosure. FIG. 2B is a structural schematic diagram of a light-emitting device package according to still another embodiment of the disclosure. FIG. 2C is a structural schematic diagram of a light-emitting device package according to yet another embodiment of the disclosure. Referring to FIG. 2A to FIG. 2C, the light-emitting device packages 200a, 200b, 200c are similar to the light-emitting device package 100 of FIG. 1A, and differences there between are as follows.

In the embodiment of FIG. 2A, the light-emitting unit 210a includes a plurality of warm white LED (WW LED) chips 211a and a plurality of cold white LED (CW LED) chips 211b. In detail, in the present embodiment, the blue LED chips 111a can be used in collaboration with different wavelength conversion materials 213a and 213b to form the WW LED chips 211a and the CW LED chips 211b. For example, when the blue LED chip 111a is used in collaboration with the wavelength conversion material 213a having an orange-biased color temperature, the WW LED chip 211a is formed. When the blue LED chip 111a is used in collaboration with the wavelength conversion material 213b having a yellow/green-biased color temperature, the CW LED chip 211b is formed. Further, in the present embodiment, based on different configuration designs of the WW LED chips 211a and the CW LED chips 211b, the color rendering index of the light-emitting unit 210a is enhanced.

In the embodiment of FIG. 2B and FIG. 2C, the light-emitting unit 210b includes a plurality of blue LED chips 111a (as shown in FIG. 2B), or the light-emitting unit 210c includes a plurality of blue LED chips 111a and a plurality of red LED chips 111b (as shown in FIG. 2C). On the other hand, in the embodiment of FIG. 2B and FIG. 2C, the wavelength conversion materials 113 of the light-emitting device packages 200b and 200c are all disposed on the platform 123 of the packaging lens 120. In this way, a risk of deterioration of the wavelength conversion material 113 caused by heating of the light-emitting device is effectively decreased.

Moreover, since the light-emitting device packages 200a, 200b and 200c all have at least one platform 123 and a plurality of optical microstructures 130, the light-emitting device packages 200a, 200b and 200c can also achieve the functions similar to that of the light-emitting device package 100, and detailed descriptions thereof are not repeated.

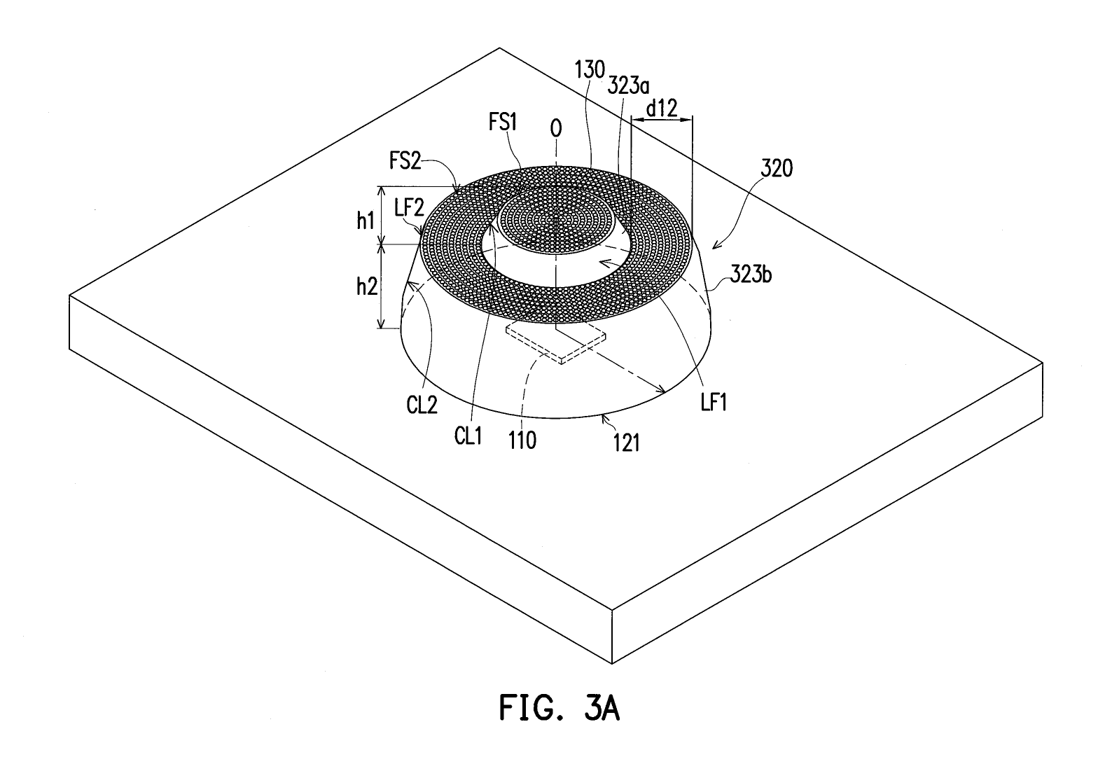

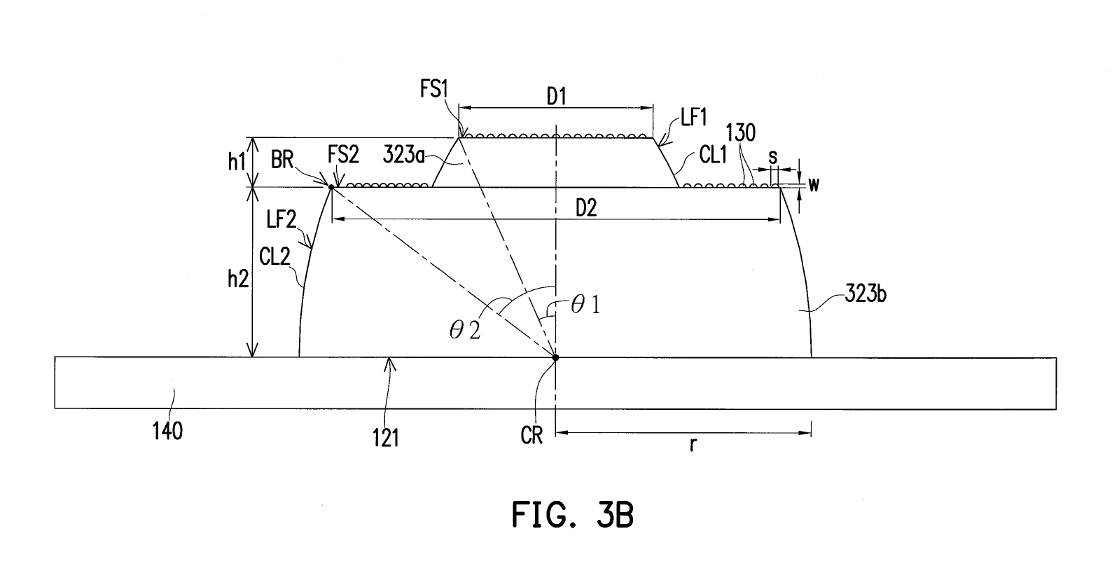

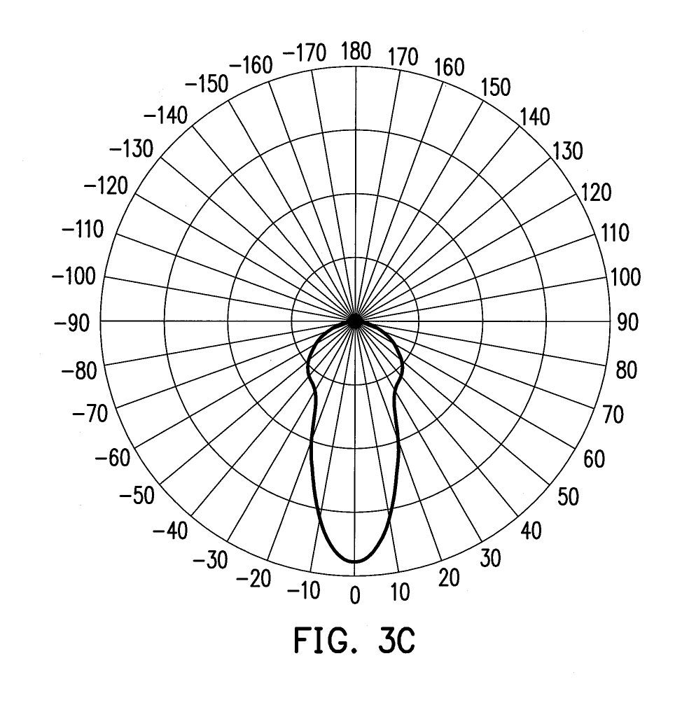

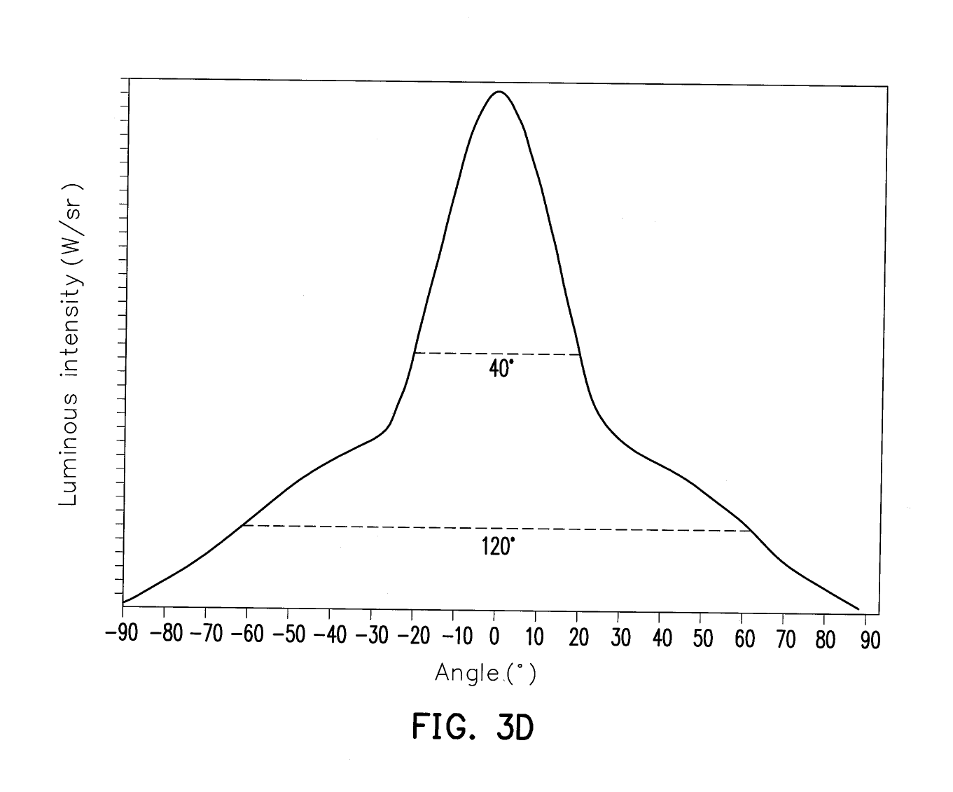

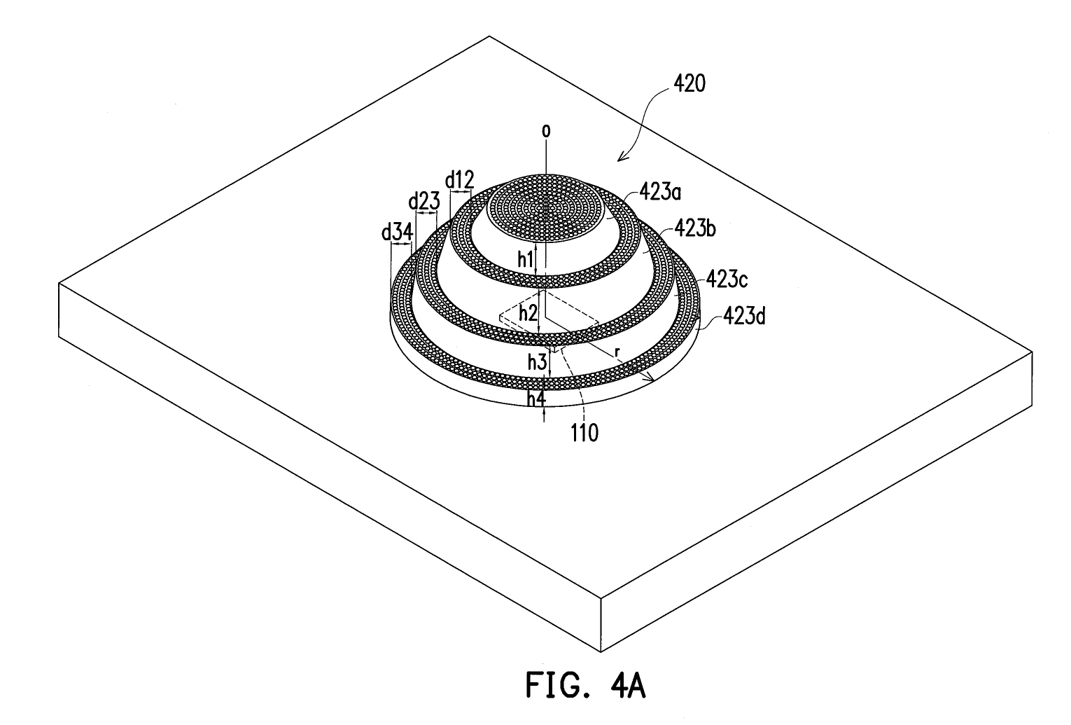

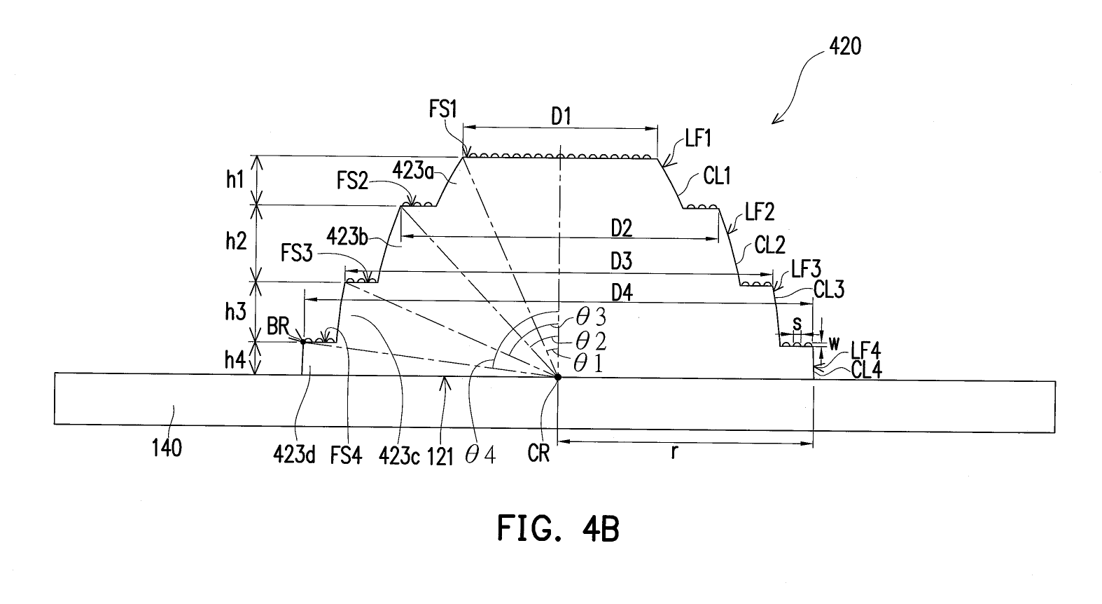

Moreover, it should be noticed that although in the embodiments of FIG. 1A to FIG. 2C, the packaging lens 120 having one platform 123 is taken as an example for descriptions, the disclosure is not limited thereto, and in other embodiments, the packaging lens 120 may also have a plurality of platforms 123, which is described below with reference of FIG. 3 and FIG. 4.

FIG. 3A is a schematic diagram of another packaging lens according to an embodiment of the disclosure. FIG. 3B is a cross-sectional view of the packaging lens of FIG. 3A. Referring to FIG. 3A and FIG. 3B, the packaging lens 320 is similar to the packaging lens 120 of FIG. 1A, and a difference there between is as follows. In the present embodiment, the at least one platform 123 of the packaging lens 320 is a plurality of platforms 323a and 323b. For example, in the present embodiment, the packaging lens 320 has two platforms 323a and 323b. In detail, the platforms 323a and 323b are stacked to each other to form a ladder shape, and size of the platform 323b close to the bottom surface 121 is greater than size of the platform 323a located away from the bottom surface 121. In other words, as shown in FIG. 3B, in the present embodiment, a maximum width D1 (or a diameter) of a platform surface FS1 of the upper platform 323a is smaller than a maximum width D2 (or a diameter) of a platform surface FS2 of the lower platform 323b. Moreover, in the present embodiment, curvatures of section lines CL1 and CL2 of side surfaces LF1 and LF2 of the two platforms 323a and 323b cut through the optical axis O are respectively a curvature R1 and a curvature R2. A vertical distance between the upper platform 323a and the platform 323b is a height h1, and a vertical distance between the platform surface FS2 of the platform 323b and the bottom surface 121 is a height h2. In the present embodiment, the height h1 is smaller than the height h2, but the disclosure is not limited thereto.

On the other hand, as shown in FIG. 3A, in the present embodiment, the two platform surfaces FS1 and FS2 of the two platforms 323a and 323b are connected by the side surface LF1 of the upper platform 323a, and the platform surface FS2 of the lower platform 323b has a ring shape. In detail, there is a distance d12 between an edge BR of the platform surface FS2 of the lower platform 323b and a junction connected to the side surface LF1 of the upper platform 323a. Moreover, in the present embodiment, an included angle θ2 between the optical axis O and a connecting line with the edge BR of the platform surface FS2 close to the bottom surface 112 and the geometric center CR of the bottom surface 121 is greater than an included angle θ1 between the optical axis O and a connecting line with the edge BR of the platform surface FS1 away from the bottom surface 112 and the geometric center CR of the bottom surface 121.

Further, when the packaging lens 320 has two platforms 323a and 323b, there are more parameters that can be used to adjust the light shape. For example, in the present embodiment, by adjusting a radius r of the packaging lens 320 on the substrate 140, the maximum widths D1 and D2 of the platform surfaces FS1 and FS2 of the packaging lens 320, the curvatures R1 and R2, the heights h1 and h2 and the distance d12, the light shape of the light beam emitted out of the packaging lens 320 can be changed, such that the light beam emitted out of the packaging lens 320 can be flexibly adjusted to reach a proper light shape effect, so as to effectively decrease a whole package height and achieve the small angle light-emitting effect.

FIG. 3C is a light shape distribution diagram when the packaging lens of FIG. 3A is applied to the light-emitting device package. FIG. 3D is an optical simulation data diagram of luminous intensity when the packaging lens of FIG. 3A is applied to the light-emitting device package. The drawing methods of FIG. 3C and FIG. 3D are similar to FIG. 1D and FIG. 1E, and details thereof are not repeated. As shown in FIG. 3C and FIG. 3D, when the packaging lens 320 is applied to the light-emitting device package 100, the light-emitting device package 100 may also achieve the small angle light-emitting effect. In detail, in the present embodiment, the divergence angle of the light-emitting device package 100 may fall within a range between 5 degrees and 90 degrees. For example, when the divergence angle of the light-emitting device package 100 is 5 degrees, the light shape of the light-emitting device package 100 is mainly distributed from −2.5 degrees to 2.5 degrees, and when the divergence angle of the light-emitting device package 100 is 90 degrees, the light shape of the light-emitting device package 100 is mainly distributed from −45 degrees to 45 degrees (as shown in FIG. 3C), but the disclosure is not limited thereto. Now, the FWHM of luminous intensity curve of the light-emitting device package 100 falls within a range between 2.5 degrees and 45 degrees. For example, when the FWHM of the luminous intensity curve of the light-emitting device package 100 is 2.5 degrees, the FWHM of the luminous intensity curve of the light-emitting device package 100 can be extended to 1.25 degrees from −1.25 degrees, and when the FWHM of the luminous intensity curve of the light-emitting device package 100 is 45 degrees, the FWHM of the luminous intensity curve of the light-emitting device package 100 can be extended to 22.5 degrees from −22.5 degrees, but the disclosure is not limited thereto. As shown in FIG. 3D, the FWHM of the luminous intensity curve of the light-emitting device package 100 is mainly extended to 20 degrees from −20 degrees. Therefore, the packaging lens 320 can also achieve the functions similar to that of the packaging lens 120, and details thereof are not repeated.

FIG. 4A is a schematic diagram of still another packaging lens according to an embodiment of the disclosure. FIG. 4B is a cross-sectional view of the packaging lens of FIG. 4A. Referring to FIG. 4A and FIG. 4B, the packaging lens 420 is similar to the packaging lens 320 of FIG. 3, and a difference there between is as follows. In the present embodiment, the packaging lens 420 has a plurality of platforms 423a, 423b, 423c and 423d, which are stacked to each other to form a ladder shape. In detail, in the present embodiment, platform surfaces FS1, FS2, FS3 and FS4 of the platforms 423a, 423b, 423c and 423d vertically adjacent to each other are respectively connected though side surfaces LF1, LF2 and LF3 of the upper platforms 423a, 423b and 423c, and platform surfaces FS2, FS3 and FS4 of the relatively lower platforms 423b, 423c and 423d respectively have a ring shape. Moreover, in the present embodiment, included angles between the optical axis O and connecting lines between the edges BR of the platforms 423a, 423b, 423c and 423d and the geometric center CR of the bottom surface 121 are respectively θ1, θ2, θ3 and θ4, wherein θ4>θ3>θ2>θ1. Moreover, by adjusting a radius r of the packaging lens 420 on the substrate 140, the maximum widths D1, D2, D3 and D4 of the platform surfaces FS1, FS2, FS3 and FS4 of the platforms 423a, 423b, 423c and 423d, the curvatures R1, R2, R3 and R4 of the side surfaces LF1, LF2, LF3 and LF4, the heights h1, h2, h3 and h4 of the platforms 423a, 423b, 423c and 423d, and distances d12, d23, d34 between the edges BR of the platform surfaces FS1, FS2, FS3 and FS4 and junctions connected to the side surfaces LF1, LF2, LF3 and LF4, the light shape of the light beam emitted out of the packaging lens 420 can also be changed, such that the light beam emitted out of the packaging lens 420 can be flexibly adjusted to reach a proper light shape effect, so as to effectively decrease a whole package height and achieve the small angle light-emitting effect. Moreover, functions of the packaging lens 420 are similar to that of the packaging lens 320, and details thereof are not repeated.

Moreover, since the packaging lenses 320 and 420 have similar functions with that of the packaging lens 120, and each of the platforms 323a, 323b, 423a, 423b, 423c, 423d can also be configured with a plurality of the optical microstructures 130. When the packaging lenses 320, 420 are applied to the light-emitting device packages 100, 200a, 200b and 200c of FIG. 1A-FIG. 2C, the functions similar as that of the light-emitting device packages 100, 200a, 200b and 200c can also be achieved, and details thereof are not repeated.

In summary, in the embodiments of the disclosure, by configuring at least one platform and a plurality of optical microstructures, the light-emitting device package may achieve the effects of high color uniformity and height-controlled light shape through one package, so as to effectively decrease the package cost and the whole package volume.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A light-emitting device package, comprising:
a substrate;
a light-emitting unit, disposed on the substrate;
a packaging lens, disposed on the substrate and wrapping the light-emitting unit, and the packaging lens having a bottom surface and comprising at least one platform, wherein the at least one platform has a side surface and a platform surface, the bottom surface of the packaging lens is connected with the platform surface of the at least one platform through the side surface of the at least one platform, and the platform surface faces away from the light-emitting unit and the bottom surface; and
a plurality of optical microstructures, located on the platform surface of the at least one platform.

2. The light-emitting device package as claimed in claim 1, wherein the at least one platform is a plurality of platforms, and the platforms are stacked to each other to form a ladder shape, and sizes of the platforms close to the bottom surface is greater than sizes of the platforms located away from the bottom surface.

3. The light-emitting device package as claimed in claim 2, wherein the platform surfaces of the vertically adjacent platforms are connected by the side surface of the upper platform, and the platform surface of the lower platform has a ring shape.

4. The light-emitting device package as claimed in claim 1, wherein the packaging lens further comprises an optical axis, the at least one platform of the packaging lens is axial symmetric relative to the optical axis, and the light-emitting unit is disposed adjacent to the optical axis.

5. The light-emitting device package as claimed in claim 4, wherein a section line of the side surface of the at least one platform cut through the optical axis is a curved line.

6. The light-emitting device package as claimed in claim 4, wherein an included angle between the optical axis and a connecting line with an edge of the platform surface of the at least one platform and a geometric center of the bottom surface falls within a range between 5 degrees and 60 degrees.

7. The light-emitting device package as claimed in claim 4, wherein the at least one platform is a plurality of platforms, and an included angle between the optical axis and a connecting line with the edge of the platform surface close to the bottom surface and the geometric center of the bottom surface is greater than an included angle between the optical axis and a connecting line with the edge of the platform surface away from the bottom surface and the geometric center of the bottom surface.

8. The light-emitting device package as claimed in claim 1, wherein the platform surface of the at least one platform is substantially parallel to a light-emitting surface of the light-emitting unit.

9. The light-emitting device package as claimed in claim 1, wherein a height of the packaging lens is smaller than or equal to 5 mm.

10. The light-emitting device package as claimed in claim 1, wherein a pitch between the optical microstructures is smaller than or equal to 500 μm.

11. The light-emitting device package as claimed in claim 1, wherein a height of the optical microstructures is smaller than or equal to 500 μm.

12. The light-emitting device package as claimed in claim 1, wherein the optical microstructures are hemispherical blocks, spherical blocks, cylindrical blocks or tapered blocks.

13. The light-emitting device package as claimed in claim 1, wherein the platform surface of the at least one platform is substantially parallel to the substrate.
